(19) United States
(12) Patent Application Publication
(10) Pub. No.: US 2003/0234392 A1
(43) Pub. Date: Dec. 25, 2003

(54) Active matrix organic light emitting diode display pixel structure

(76) Inventors: Nein-Hui Kung, Miaoli (TW); Yung-Hui Yeh, Hsinchu (TW)

Correspondence Address: BIRCH STEWART KOLASCH & BIRCH, PO BOX 747, FALLS CHURCH, VA, 22040-0747, US

(21) Appl. No.: 10/265,266

(22) Filed: Oct. 7, 2002

(30) Foreign Application Priority Data
Jun. 25, 2002 (TW) 91113889

(51) Int. Cl. H01L 29/06; H01L 31/0328; H01L 31/0336; H01L 31/072; H01L 31/109

(52) U.S. Cl. 257/13

(57) ABSTRACT

An active matrix organic light emitting diode display pixel structure. In the pixel structure of the present invention, a switching transistor has a gate terminal coupled to a scan signal and a source terminal coupled to a data signal. A storage capacitor has two terminals coupled to a drain terminal of the first transistor and a reference voltage respectively. An OLED has an anode coupled to a drain terminal of the second transistor and a cathode coupled to a first voltage. A plurality of driving transistors is coupled in cascode, wherein the first terminal of the first diving transistor of the driving transistors is coupled to a second voltage, and a second terminal of the final diving transistor of the driving transistors is coupled to the anode of the OLED, and an equivalent channel width/length (W/L) ratio of the driving transistors does not exceed 0.2.

### BACKGROUND OF THE INVENTION

1. Field of the Invention

The present invention relates in general to a pixel structure. In particular, the present invention relates to an active matrix organic light emitting diode (OLED) display pixel structure that achieves high-gray scale and improved reliability of the elements by modifying the dimensions of the driving transistor.

2. Description of the Related Art

A common feature in LCD panels is the use of thin-film transistors (TFT) in an active address scheme, which relaxes the limitation in direct addressing. The success of LCD technology is in large part due to the rapid progress in the fabrication of large-area TFTs. The almost ideal match between TFT switching characteristics and electrooptic LCD display elements also plays a key role.

A major drawback of TFT-LCD panels is the requirement for backlighting. This is because the transmission factor of the TFT-LCD, particularly of colored panels is poor, typically about 2-3 percent. Power consumption for backlit TFT-LCD panels is considerable and adversely affects portable display applications requiring battery operatios.

The need for backlighting also impairs miniaturization of the flat panel. For example, panel depth must be increased to accommodate the backlight unit. Using a typical tubular cold-cathode lamp, the added depth is ¾ to 1 inch. Backlighting also adds extra weight to the FED.

An ideal solution is a low power emitting display that eliminates the need for backlighting. A particularly attractive candidate is the thin-film-transistor-electroluminescent (TFT-EL) display. In TFT-EL displays, the individual pixels can be addressed to emit light and auxiliary backlighting is not required.

However, since the ZnS-EL requires a high drive voltage of more than a hundred volts, the switching CdSe TFT element must be designed to handle such a high voltage swing. The reliability of the high-voltage TFT is then compromised.

Recently, organic EL materials have been devised. These materials suggest themselves as candidates for display media in TFT-EL devices. Organic EL media has two important advantages: it is highly efficient and has low voltage requirements. The latter characteristic distinguishes it over other thin-film emissive devices.

The particular properties of organic EL material that make it ideal for TFT are summarized herein.

Typically, the organic EL cell requires a voltage in the range of 4 to 10 volts depending on the light output level and the cell impedance. The voltage required to produce a brightness of about 20 FL (Foot-Lamberts), is about 5V. This low voltage is highly attractive for a TFT-EL panel, as the need for the high-voltage TFT is eliminated. Furthermore, the organic EL cell can be driven by DC or AC current. As a result the driver circuit is less complicated and less expensive.

The luminous efficiency of the organic EL cell is as high as 4 lumens per watt. The current density to drive the EL cell to produce a brightness of 20 FL is about 1 mA/cm². Assuming a 100% duty excitation, the power needed to drive a 400 cm² full-page panel is only about 2.0 watts. The low power need certainly meets the portability criteria of the flat panel display.

Organic EL device can be fabricated at about room temperature. This is a significant advantage compared with inorganic emissive devices, which require high-temperature (>300° C.) processing. The high-temperature processes required to make inorganic EL devices can be incompatible with the TFT.

FIG. 1 shows a conventional pixel structure of an active matrix OLED display. In FIG. 1, switching transistor M1 turns on such that data signal DATA charges storage capacitor C1 when the switching transistor receives a scan signal SCAN. Further, driving transistor M2 turns on such that organic emissive device OLED illuminates when the voltage stored at the storage capacitor C1 exceeds threshold voltage of the driving transistor M2. However, in the conventional pixel structure, threshold voltage of the driving transistor M2 will vary with process variations. Consequently, the convention pixel structure shown in FIG. 1 shows poor reliability, poor lightness unity and cannot achieve high-gray scale.

### SUMMARY OF THE INVENTION

It is an object of the present invention to provide a pixel structure for active matrix OLED display that can achieve the high-gray scale by modifying the dimensions of the driving transistor to modify the I-V curve of the driving transistor.

It is also an object of the present invention to provide a pixel structure of an active matrix OLED display that can achieve the high-gray scale and improve the reliability of the driving transistor.

According to the first embodiment of the active matrix OLED display pixel structure of the present invention, a first transistor has a gate terminal coupled to a scan signal and a source terminal coupled to a data signal. A storage capacitor has two terminals coupled to a drain terminal of the first transistor and a reference voltage respectively. A second transistor has a gate terminal coupled to the drain of the first transistor and a source terminal coupled to a second voltage. Further, an OLED has an anode and a cathode coupled to a drain terminal of the second transistor and a second voltage respectively, wherein the channel width/length ratios of the second transistor is below 0.2.

According to the first embodiment of the active matrix OLED display pixel structure of the present invention, a first transistor has a gate terminal coupled to a scan signal and a source terminal coupled to a data signal. A storage capacitor has two terminals coupled to a drain terminal of the first transistor and a reference voltage respectively. An OLED has a cathode coupled to a first voltage and an anode. Furthermore, a plurality of driving transistors coupled in cascode, wherein the first terminal of the first diving transistor deposited at the first stage of the driving transistors is coupled to a second voltage, and a second terminal of the final diving transistor deposited at the final stage of the driving transistors is coupled to an anode of the OLED, and an equivalent channel width/length (W/L) ratios of the driving transistors is below 0.2.

### BRIEF DESCRIPTION OF THE DRAWINGS

FIG. 1 shows a conventional pixel structure of the active matrix OLED display.

FIG. 2 shows a pixel structure of the active matrix OLED display according to the first embodiment of the present invention.

FIG. 3 is a sectional drawing of the driving transistor in the first embodiment.

FIG. 4 shows a current-voltage curve illustrating the relationship between current and voltage of driving transistors with different W/L ratios.

FIG. 5 shows the relationship between driving current and current variation of driving transistors with different W/L ratios.

FIG. 6 shows another relationship between driving current and current variation of driving transistors with different W/L ratios.

FIG. 7 is another aspect of the first embodiment of the present invention.

FIG. 8 shows a pixel structure of the active matrix OLED display according to the second embodiment of the present invention.

FIG. 9 shows a pixel structure of the active matrix OLED display according to the second embodiment of the present invention.

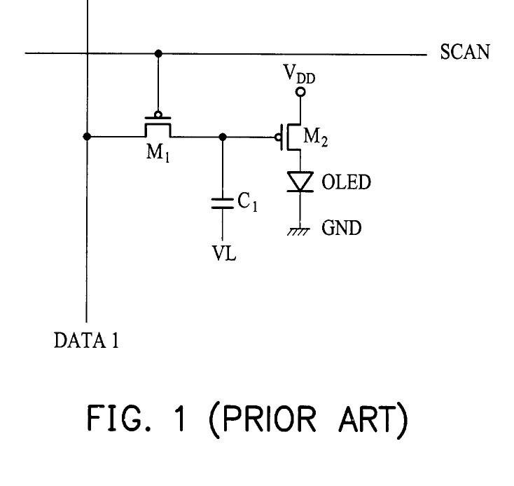

### DETAILED DESCRIPTION OF THE INVENTION

### The First Embodiment

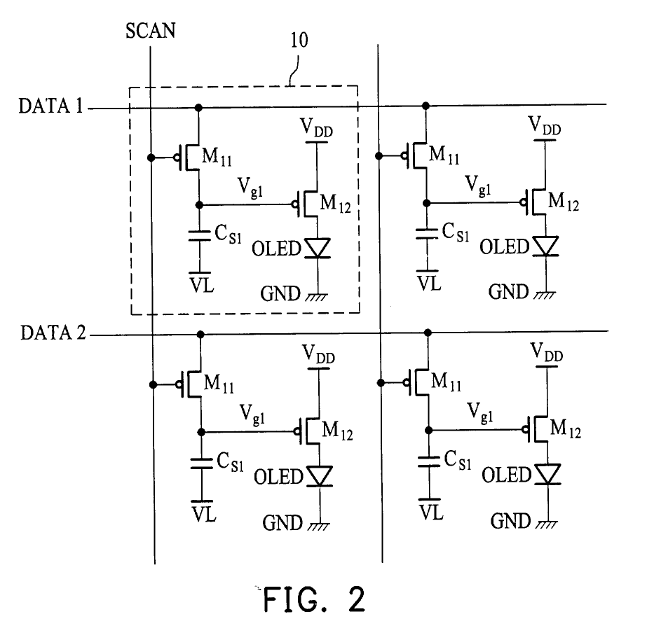

FIG. 2 shows a pixel structure of the active matrix OLED display according to the first embodiment of the present invention, wherein the pixel structure 10 is composed of a first transistor M11, a storage capacitor CS1, a second transistor M₁₂ and a organic light emitting diode OLED.

The first transistor M11 has a gate terminal coupled to a scan signal SCAN, a source terminal coupled to a data signal DATA1. The storage capacitor CS1 has two terminals coupled to a drain terminal of the first transistor and a reference voltage VL respectively. The reference voltage VL for example is ground.

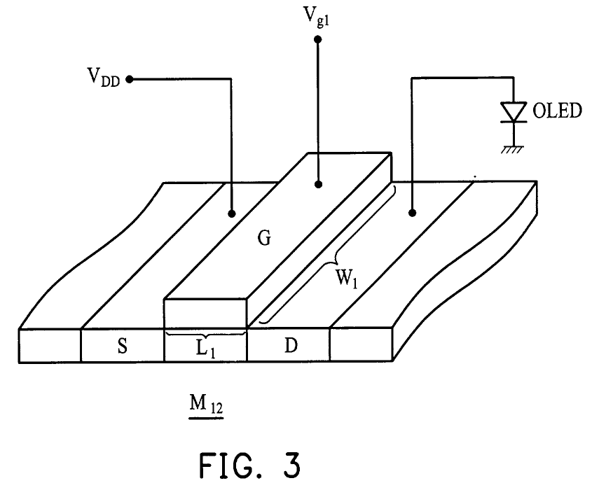

The second transistor M12 has a gate terminal coupled to the drain terminal of the first transistor M11, and a source terminal coupled to a first voltage VDD. Further, the organic light emitting diode OLED has an anode coupled to a drain terminal of the second transistor, and a cathode coupled to a second voltage GND. FIG. 3 is a sectional drawing of the driving transistor in FIG. 2, wherein the channel width/length (W1/L1) of the second transistor M12 is below 0.2, for example 1.5 or 1.0.

The first transistor M₁₁ turns on and off according to the scan signal SCAN, and the second transistor turns on to produce current such that the organic light emitting diode OLED illuminates according to the data signal DATA1.

Operation of the active matrix organic light emitting diode display pixel structure according to the present invention follows.

First, the first transistor M11 turns on such that the data signal DATA1 charges the storage capacitor CS1 when the scan signal SCAN coupled to the gate terminal of the first transistor M11 is high potential, that is, exceeds the threshold voltage of the first transistor M11.

The second transistor M12 turns on and produces a corresponding driving current to the organic light emitting diode OLED according to a voltage Vg stored at the storage capacitor CS1, when the voltage Vg exceeds the threshold voltage of the second transistor M12. Consequently, the organic light emitting diode OLED illuminates according to the driving current.

To achieve high-gray scale, the present invention modifies the channel width/length ratios (W1/L1) of the second transistor M12 to below 0.2.

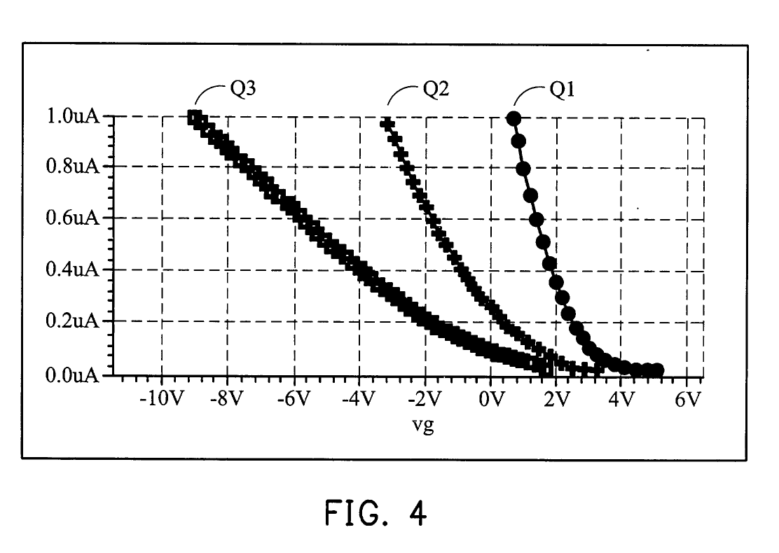

FIG. 4 shows a current-voltage curve to present the relationship between current and voltage of driving transistors with different W/L ratios. In the first embodiment of the present invention, the first and second transistors M11 and M12 are P-type transistors. As shown in FIG. 4, curves Q1, Q2 and Q3 correspond to channel width/length ratios of 1.0, 0.2 and 0.08. As shown in FIG. 4, the ratios of driving current and driving voltage decrease as those of channel width/length decrease. In other words, the linear region of the driving transistor is increased such that the driving current of the driving transistor does not enter saturation region quickly as the channel width/length ratios decrease. Consequently, the high-gray scale of the pixel structure is achieved.

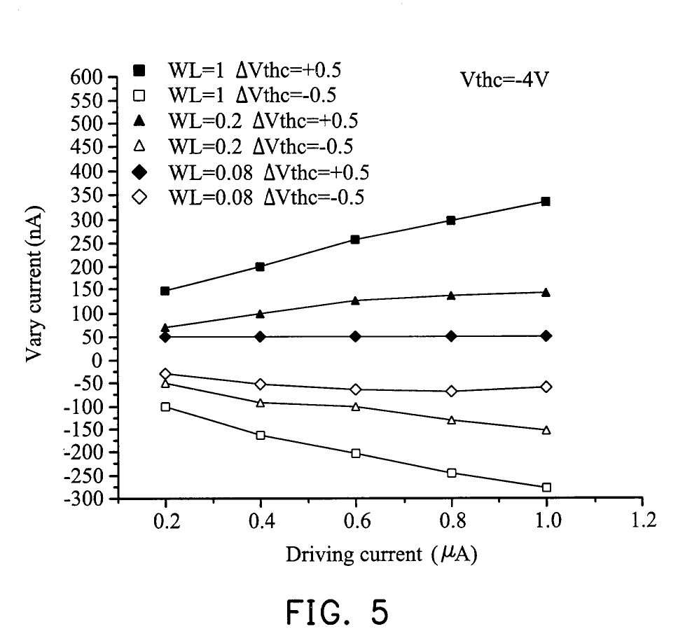

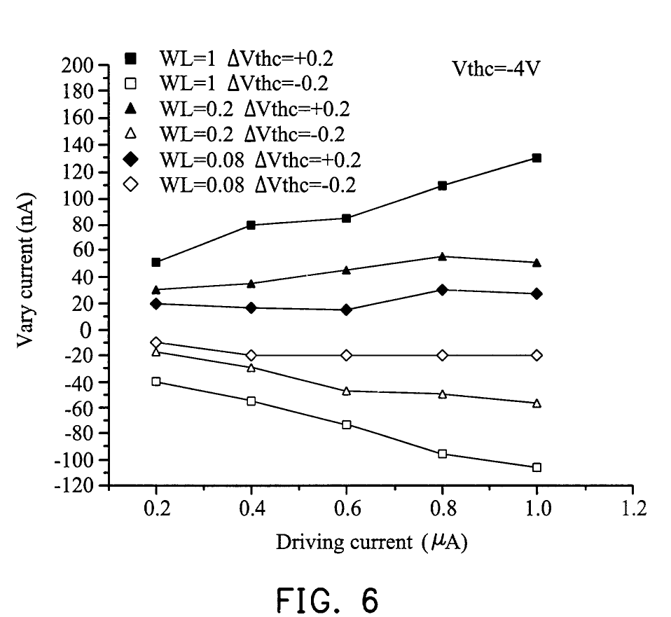

FIG. 5 shows the relationship between driving current and current variation of driving transistors with different W/L ratios, wherein the driving transistor has a threshold voltage variation of ±0.5 volts caused by process variation. FIG. 6 shows another relationship between driving current and current variation of driving transistors with different W/L ratios, wherein the driving transistor has a threshold voltage variation of ±0.2 volts caused by process variation. In view of FIG. 5 and FIG. 6, as the channel width/length ratio of the driving transistor reduces and the driving current variation of the driving transistor caused by threshold voltage variation is smaller. Consequently, the present invention modifies the channel width/length ratio of the driving transistor to below 0.2, and the reliability of the driving transistor of the pixel structure is thus improved.

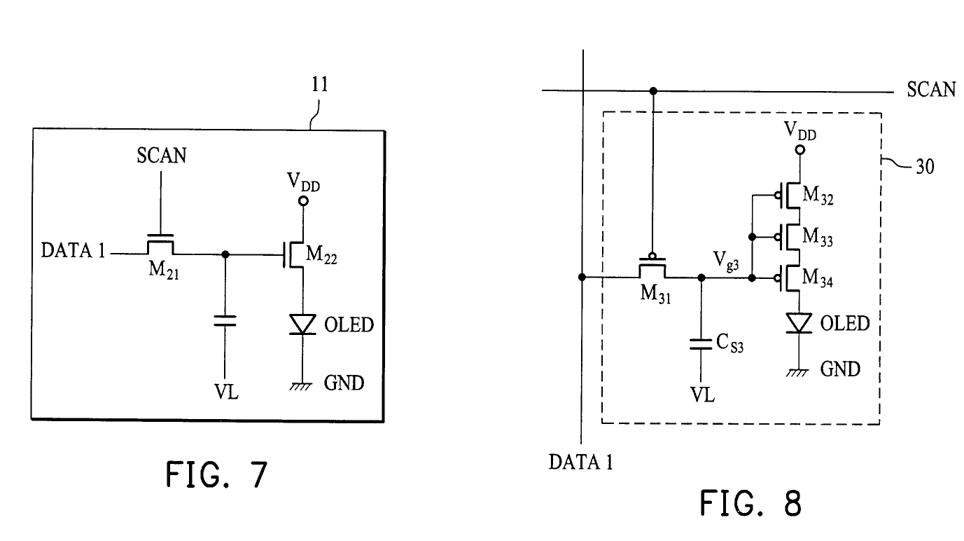

FIG. 7 shows another aspect of the first embodiment of the present invention, wherein the first and second transistors M21 and M22 are N-type thin-film transistors. Furthermore, the channel width/length ratios of the second transistor M22 is also below 0.2 such that the object of achieving high-gray scale and improving reliability of the driving transistor is obtained as well.

### The Second Embodiment

FIG. 8 shows a pixel structure of an active matrix OLED display according to the first embodiment of the present invention, wherein the pixel structure 30 is composed of a switching transistor M31, a storage capacitor CS1, a organic light emitting diode OLED and first to third driving transistors M32-M34.

The switching transistor M31 has a gate terminal coupled to a scan signal SCAN, a source terminal coupled to a data signal DATA1. The storage capacitor CS3 has two terminals coupled to a drain terminal of the switching transistor M31 and a reference voltage VL respectively. The reference voltage VL for example is ground or voltage source VDD.

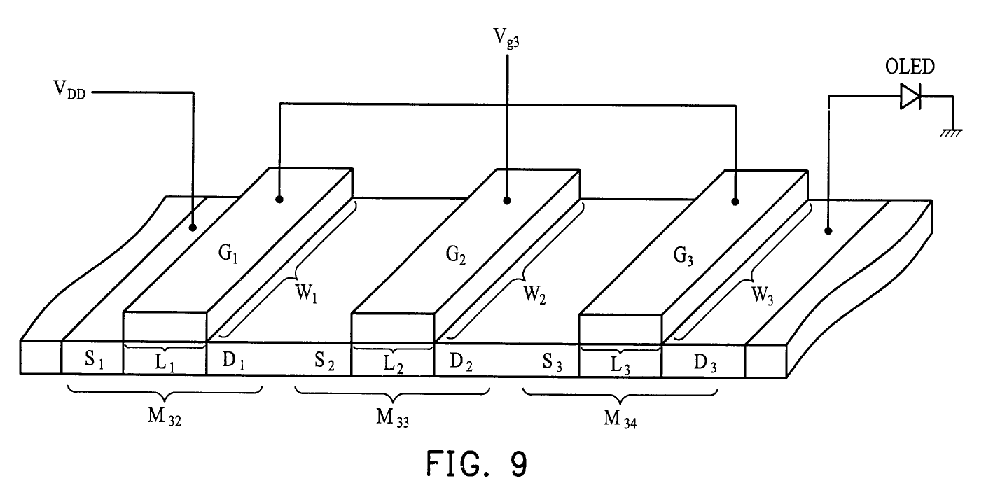

The first driving transistor M32 has a gate terminal coupled to the drain terminal of the switching transistor M11, and a source terminal coupled to a first voltage VDD. A source terminal of the second driving transistor M32 is coupled to the drain terminal of the first driving transistor M32, and a source terminal of the third driving transistor M34 is coupled to the drain terminal of the second driving transistor M33. The drain terminal of the third driving transistor M34 is coupled to an anode of the organic light emitting diode OLED and the cathode of the OLED is coupled to ground. The gate terminals of the first to third driving transistors are coupled to switching transistor M31. FIG. 9 is a sectional drawing of the driving transistor in FIG. 8, the channel width/length ratios of the first to third driving transistors M32, M33 and M34 are W1/L1, W2/L2, W3/L3 respectively, and the equivalent channel width/length ratios (Ws/Ls) of three driving transistor M32 to M34 is below 0.2, for example 0.8 or 1.0.

The switching transistor M31 turns on and off according to the scan signal SCAN, and the three driving transistors M32-M34 turn on to produce current such that the organic light emitting diode OLDE illuminates according to the data signal DATA1.

Operation of the active matrix organic light emitting diode display pixel structure 30 according to the second embodiment of the present invention follows.

First, the switching transistor M31 turns on such that the data signal DATA1 charges the storage capacitor CS3 when the scan signal SCAN coupled to the gate terminal of the switching transistor M31 is high potential, that is, exceeds the threshold voltage of the switching transistor M31.

The first to third driving transistors M32-M34 all turn on and produce a corresponding driving current to the organic light emitting diode OLED according to a voltage Vg stored at the storage capacitor CS3, when the voltage Vg exceeds the threshold voltages of the three driving transistors M32-M34. Consequently, the organic light emitting diode OLED illuminates according to the driving current.

To achieve high-gray scale, the present invention modifies the equivalent channel width/length ratios (Ws/Ls) of the three driving transistors M32-M34 also to below 0.2. In other words, the linear region of the driving transistors M32-M34 is increased such that the driving current of the driving transistors M32-M34 does not enter saturation region quickly if channel width/length ratios decrease. Consequently, the high-gray scale of the pixel structure is achieved.

Furthermore, the driving current output to OLED from the three driving transistors M32-M34 is smaller than a single driving transistor based on the same driving voltage Vg because three driving transistors M32-M34 are coupled in cascode. Namely, the ratios of driving current increment and driving voltage increment of three driving transistors is decreased, and the linear region of the equivalent driving transistor composed of transistors M32-M34 is increased and the effect of high-gray scale of the pixel structure is improved. Further, the present invention can share the luminescence variation caused by the threshold voltage variation of the driving transistors when the threshold voltage is varied by process variation because the three driving transistors are coupled in cascode. Consequently, the second embodiment also can improve the reliability of the driving transistor and achieve high-gray scale of the pixel structure.

The switching transistor M31, the first driving transistor M32, the second driving transistor M33 and third driving transistor M34 are not only implemented by P-type thin-film transistors, but also implemented by N-type thin-film transistors. The most important point is that the equivalent channel width/length ratios must not exceed 0.2, and then the object of achieving high-gray scale and improving reliability of the driving transistor is obtained as the first embodiment.

Finally, while the invention has been described by way of example and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A pixel structure of the active matrix organic light emitting diode display, comprising:
a first transistor having a gate terminal coupled to a scan signal and a source terminal coupled to a data signal;
a storage capacitor having two terminals coupled to a drain terminal of the first transistor and a reference voltage respectively;
a second transistor having a gate terminal coupled to the drain terminal of the first transistor and a source terminal coupled to a first voltage, wherein a channel width/length (W/L) ratio is below 0.2; and
an organic light emitting diode (OLED) having an anode coupled to a drain terminal of the second transistor and a cathode coupled to a second voltage.

2. The pixel structure as claimed in claim 1, wherein the first and second transistors are Thin-film transistors.

3. The pixel structure as claimed in claim 2, wherein the thin-film transistors are N-type thin-film transistors.

4. The pixel structure as claimed in claim 2, wherein the thin-film transistors are P-type transistors.

5. The pixel structure as claimed in claim 1, wherein the second voltage is ground.

6. The pixel structure as claimed in claim 1, wherein the first voltage is a voltage source.

7. The pixel structure as claimed in claim 1, wherein the reference voltage is ground.

8. A pixel structure of the active matrix organic light emitting diode display, comprising:
a switching transistor having a gate terminal coupled to a scan signal and a source terminal coupled to a data signal;
a storage capacitor having two terminals coupled to a drain terminal of the first transistor and a reference voltage respectively;
an organic light emitting diode (OLED) having a cathode coupled to a first voltage; and
a plurality of driving transistors coupled in cascode, wherein the first terminal of the first diving transistor is deposited at the first stage of the driving transistors coupled to a second voltage, and a second terminal of the final diving transistor is deposited at the final stage of the driving transistors coupled to an anode of the OLED, and an equivalent channel width/length (W/L) ratio of the driving transistors is below 0.2.

9. The pixel structure as claimed in claim 8, wherein the switching transistor is a thin-film transistor.

10. The pixel structure as claimed in claim 9, wherein the switching transistor is an N-type thin-film transistor.

11. The pixel structure as claimed in claim 9, wherein the switching transistor is a P-type thin-film transistor.

12. The pixel structure as claimed in claim 10, wherein the plurality of driving transistors comprises P-type thin-film transistors.

13. The pixel structure as claimed in claim 10, wherein the plurality of driving transistors comprises N-type thin-film transistors.

14. The pixel structure as claimed in claim 10, wherein the plurality of driving transistors comprises N-type thin-film transistors.

15. The pixel structure as claimed in claim 8, wherein the second voltage is a voltage source.

16. The pixel structure as claimed in claim 15, wherein the first voltage is ground.

17. The pixel structure as claimed in claim 1, wherein the reference voltage is ground.
